(19) United States
(12) Patent Application Publication
(10) Pub. No.: US 2007/0029539 A1
(43) Pub. Date: Feb. 8, 2007

(54) LIGHT-EMITTING ELEMENT ARRAY AND DISPLAY APPARATUS

(75) Inventors: MASATAKA YASHIMA, Tokyo (JP); Keiji Okinaka, Kawasaki-shi (JP); Akihito Saitoh, Yokohama-shi (JP); Naoki Yamada, Tokyo (JP); Toshinori Hasegawa, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/459,571

(22) Filed: Jul. 24, 2006

(30) Foreign Application Priority Data
Aug. 4, 2005 (JP) 2005-226658
Jul. 11, 2006 (JP) 2006-189960

(51) Int. Cl. H01L 29/06

(52) U.S. Cl. 257/13

(57) ABSTRACT

There is provided a light-emitting element array having a plurality of light-emitting elements of different emission colors each comprising a light extraction electrode, a reflecting electrode, and an organic layer disposed between the electrodes, said organic layer comprising a light-emitting layer and a carrier-transporting layer disposed between the light-emitting layer and the reflecting electrode, wherein the geometrical distances between the reflecting electrode and light-emitting layer are the same irrespective of the emission color, and the specific relational equations (1), (2), and (3) are satisfied.

### BACKGROUND OF THE INVENTION

1. Field of the Invention

The present invention relates to an array having a plurality of light-emitting elements using an organic compound. More specifically, the present invention relates to an organic electroluminescent (EL) element array having a plurality of organic EL elements which emit light by applying an electric field to a thin film composed of an organic compound.

2. Description of the Related Art

An organic EL element is an element in which a thin film containing a fluorescent organic compound is interposed between an anode and a cathode; electrons and holes are injected from the respective electrodes to generate excitons of the fluorescent compound; and a light radiated when the excitons return to ground state is utilized.

A number of attempts have been made to obtain a maximum efficiency and a maximum luminance in such an organic EL element by controlling the thickness of a thin film containing an organic compound interposed between an anode and a cathode. For example, Japanese Patent Application Laid-Open Nos. H04-137485 and H04-328295 each disclose a method in which the thickness of a layer between a light-emitting layer and a cathode is controlled such that a light generated from the light-emitting layer and a light reflected from the cathode interfere with each other, thereby increasing the quantity of light as substantially extracted.

In addition, Japanese Patent Application Laid-Open No. H07-240277 discloses a method in which a high-refractive-index transparent electrode is used as a light extraction side electrode and an optical path (or optical distance) between a light-emitting layer and the light extraction side electrode is controlled, thereby improving an interference effect.

Furthermore, as shown in Japanese Patent Application Laid-Open No. H10-177896, an attempt has been made in which an anode and a cathode are formed of a combination of a reflective electrode and a semi-transmissive electrode to constitute a microresonator, thereby improving an interference effect.

However, the above-mentioned techniques have a problem that the thickness of an organic layer, a transparent electrode, or the like needs to be changed for each emission color, so that a production process of a display apparatus becomes complicated.

The present invention has been accomplished in view of the above problem, and an object of the present invention is to achieve a light-emitting element array having a high efficiency and an excellent color purity with a simple constitution.

### SUMMARY OF THE INVENTION

That is, the present invention provides a light-emitting element array having a plurality of light-emitting elements of different emission colors each comprising a light extraction electrode, a reflecting electrode, and an organic layer disposed between the electrodes, said organic layer comprising a light-emitting layer and a carrier-transporting layer disposed between the light-emitting layer and the reflecting electrode, wherein the geometrical distances between the reflecting electrode and light-emitting layer are the same irrespective of the emission color, and the following relational equations (1), (2), and (3) satisfied:

$$\begin{matrix}{λ}_{1} > {λ}_{2} > {λ}_{3} > ⋯ > {λ}_{n} \\ {α}_{1} + {δ}_{1} / 2 π = m \\ {α}_{2} + {δ}_{2} / 2 π = m + 1 \\ \begin{matrix}{α}_{3} + {δ}_{3} / 2 π = m + 2 \\ ⋮\end{matrix} & ( 1 ) \\ {α}_{n} + {δ}_{n} / 2 π = m + n - 1 \\ \vert 2 {L}_{1} / {λ}_{1} - {α}_{1} \vert \leq 1 / 8 \\ \vert 2 {L}_{2} / {λ}_{2} - {α}_{2} \vert \leq 1 / 8 \\ \begin{matrix}\vert 2 {L}_{3} / {λ}_{3} - {α}_{3} \vert \leq 1 / 8 \\ ⋮\end{matrix} & ( 2 ) \\ \vert 2 {L}_{n} / {λ}_{n} - {α}_{n} \vert \leq 1 / 8 & ( 3 )\end{matrix}$$

wherein λ₁, λ₂, λ₃, . . . , λₙ represent emission peak wavelengths of the respective light-emitting elements of different emission colors, δ₁, δ₂, δ₃, . . . , δₙ represent phase shift amounts for the respective emission colors of the reflecting electrode, L₁, L₂, L₃, . . . , Lₙ represent optical paths (or optical distances) between the reflecting electrode and light-emitting layer of the respective light-emitting elements of different emission colors, m represents a natural number, and n represents a natural number more than 2.

Further, a display apparatus of the present invention comprises the above-mentioned light-emitting element array.

According to the present invention, an improvement in light extraction efficiency and an improvement in color purity can be achieved while layers other than a light-emitting layer each have the same structure.

Further features of the present invention will become apparent from the following description of exemplary embodiments (with reference to the attached drawings).

### BRIEF DESCRIPTION OF THE DRAWINGS

FIG. 1 is a schematic cross-sectional view showing an example of a display apparatus using an organic EL element array of the present invention;

FIG. 2 is a conceptual view showing a light-emitting region of an organic EL element;

FIG. 3 is a conceptual view showing an interference effect resulting from multiple reflections;

FIG. 4 is a schematic cross-sectional view showing another example of a display apparatus using an organic EL element array of the present invention;

FIG. 5 is a schematic cross-sectional view showing still another example of a display apparatus using an organic EL element array of the present invention; and

FIG. 6 is a schematic cross-sectional view showing yet another example of a display apparatus using an organic EL element array of the present invention.

### DESCRIPTION OF THE EMBODIMENTS

Hereinafter, the present invention will be described in detail with reference to preferred embodiments.

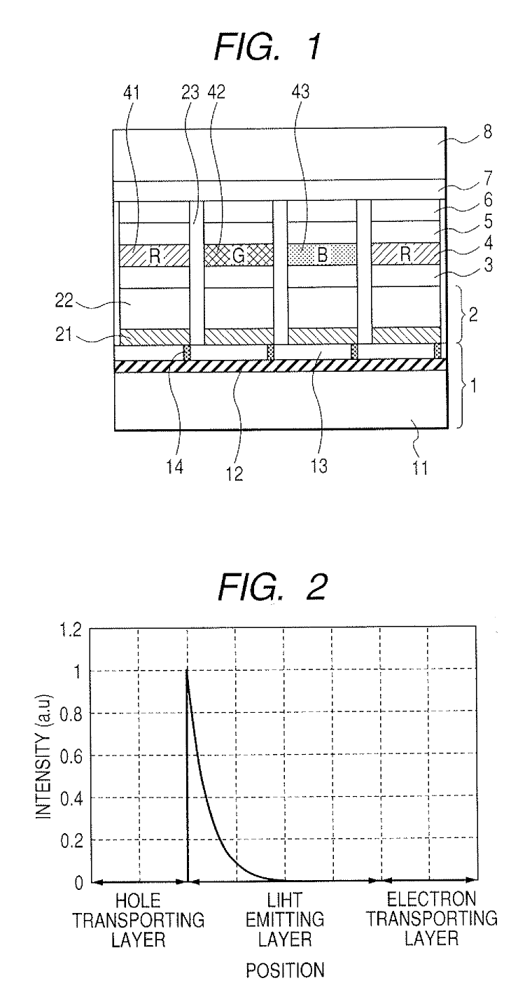

FIG. 1 is a schematic cross-sectional view of a top emission type active matrix display apparatus using an organic EL element array according to the present invention.

Each of organic EL elements is constituted by sequentially disposing, on a substrate 1, an anode 2, a hole-transporting layer 3, a light-emitting layer 4, an electron-transporting layer 5, an electron injection layer 6, a cathode 7, and a protective layer 8. The anode 2 functions as a reflecting electrode, and the cathode 7 functions as a light extraction electrode. For example, in a display apparatus of three colors of red, green, and blue, a red-light-emitting layer 41, a green-light-emitting layer 42, and a blue-light-emitting layer 43 which effect electroluminescence of red, green, and blue, respectively are formed. Flowing a current through these EL elements allows holes as carriers injected from the anode 2 and electrons as carriers injected from the cathode 7 to recombine with each other in each of the red-, green-, and blue-light-emitting layers, whereby red light, green light, and blue light are emitted therein, respectively. The peak wavelength of each emission color is 600 nm to 680 nm for red, 500 nm to 560 nm for green, and 430 nm to 490 nm for blue.

At this time, the region in which a light is emitted is determined by a relationship among the hole-transporting layer 3, the light-emitting layer 4, and the electron-transporting layer 5. In general, as shown in FIG. 2, the intensity of emitted light is maximum at an interface between the hole-transporting layer 3 and the light-emitting layer 4, and gradually attenuates toward the inside of the light-emitting layer 4. In addition, the emitted light can be extracted from either the substrate 1 side or the protective layer 8 side. In the case of an active matrix drive display apparatus like this embodiment, from the viewpoint of securement of an aperture ratio, it is advantageous to adopt the so-called top emission structure in which light is extracted from the protective layer 8 side.

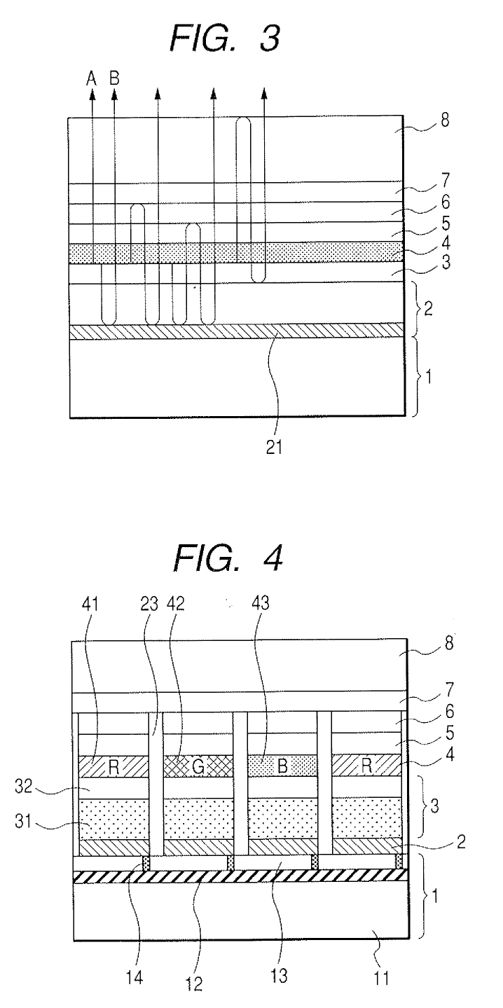

As shown in FIG. 3, when electroluminescence occurs with the intensity being maximal at the interface with the hole-transporting layer 3 within the light-emitting layer 4, a light emitted as a result of the electroluminescence repeatedly undergoes reflection, refraction, transmission, absorption, and the like owing to a difference in refractive index between constituent layers before being extracted to the outside. Here, when an influence of interference is taken into consideration, an interference effect between a light (A) directly traveling from an emission position (the position at which an emission intensity distribution shows a peak) in a light extraction direction and a light (B) which is reflected by the reflecting surface of the reflecting electrode (anode 2) before traveling in the light extraction direction is largest. In order to utilize the interference effect, it is required to adjust the optical path between the emission position and the reflecting surface of the reflecting electrode (anode 2). At this time, it is noted that the emission position is substantially the interface between the hole-transporting layer 3 and the light-emitting layer 4. Accordingly, in the organic EL element array of this embodiment, it is possible to control the interference effect by adjusting the optical path between the interface on the reflecting electrode (anode 2) side of the light-emitting layer 4 and the reflecting surface of the reflecting electrode (anode 2). Incidentally, the term “optical path (or optical distance)” as herein employed refers to a product of a distance and an absolute refractive index, and the value of the absolute refractive index will vary depending on a wavelength.

In particular, in the structure in which the light extraction side electrode (cathode 7) is transparent and the transparent protective layer 8 is provided thereon like this embodiment, the reflectance at the interface of the transparent electrode (cathode 7) is relatively small. As a result, the interference effect resulting from resonance (cavity) is smaller than the above-mentioned interference effect between the light (A) and the light (B). In view of the foregoing, it has been found that adjusting the optical path L between the light (A) and the beam (B), that is, between the emission position (the position at which the emission intensity distribution shows a peak) and the reflecting surface of the reflecting electrode first enables the degree of interference to be controlled.

Accordingly, when the optical paths between the interface on the reflecting electrode (anode 2) side of the light-emitting layer 4 and the reflecting surface of the reflecting electrode (anode 2) for the respective emission colors are represented by L_{R}, L_{G}, and L_{B}, an improvement in light extraction efficiency owing to interference can be expected when the following relational equations (4) are satisfied for emission peak wavelengths λ_{R}, λ_{G}, and λ_{B} of red, green, and blue:
2L_{R}/λ_{R}+δ_{R}/2π=m
2L_{G}/λ_{G}+δ_{G}/2π=m′
2L_{B}/λ_{B}+δ_{B}/2π=m″ (4)
wherein m, m′, and m″ each represent a natural number, and δ_{R}, δ_{G}, and δ_{B} represent phase shift amounts for the respective emission colors at the time of reflection. In addition, m (or m′ or m″) as a number on the right side of the expression is defined as an order of interference. The phase shift δ is an amount representing a shift in phase occurring at the time of reflection of light, and can be represented by the following relational equation (5):
δ=arctan [(2nᵢkᵣ)/(nᵢ²−nᵣ²−kᵣ²)] (5)

wherein nᵣ and kᵣ each represent the complex refractive index of the reflecting surface of the reflecting electrode, and nᵢ represents the refractive index of a light incidence side thereof.

Here, from the viewpoint of simplification of a production process of a display apparatus, it is preferred that layers other than the light-emitting layer each have a common structure as far as possible. Accordingly, in the light-emitting element array of the present invention, the distances between the interface on the reflecting electrode (anode 2) side of the light-emitting layer 4 and the reflecting surface of the reflecting electrode (anode 2) for the respective emission colors are made identical to each other. At this time, L_{R}, L_{G}, and L_{B} differ from one another only by about a wavelength dispersion of a substance interposed between the emission position and the reflecting surface of the reflecting electrode and take substantially equal values.

In addition, by making the distances between the interface on the reflecting electrode side of the light-emitting layer 4 and the reflecting surface of the reflecting electrode for the respective colors equal to one another, it is possible to provide a light-emitting element array or display apparatus having less unevenness. The reduction of the unevenness can improve the coverage property of the protective layer 8.

Meanwhile, at wavelengths in regions between the peak wavelengths λ_{R}, λ_{G}, and λ_{B} of the respective emission colors of red, green, and blue, from the viewpoint of improvement in color purity, it is preferable that lights optically weaken each other. This is because weakening each other enables a sharper EL spectrum to be extracted, and hence can contribute to improvement in color purity, and, furthermore, to the expansion of a color reproduction range that can be displayed.

In view of the above-mentioned two points, the inventors have found the following relational equations (4′) as conditions for striking a balance between improvement in light extraction efficiency and improvement in color purity:
2L_{R}/λ_{R}+δ_{R}/2π=m
2L_{G}/λ_{G}+δ_{G}/2π=m+1
2L_{B}/λ_{B}+δ_{B}/2π=m+2 (4″)

wherein δ_{R}, δ_{G}, and δ_{B} represent phase shift amounts for the respective emission colors of reflecting electrodes and m represents a natural number.

That is, matching the peak wavelengths of the emission colors with continuous orders serving as conditions for mutual strengthening (reinforcement) through an interference effect causes lights to strengthen (reinforce) each other at the peak wavelengths and to weaken each other at wavelengths in regions between the peak wavelengths. As a result, it becomes possible to strike a balance between the improvement in light extraction efficiency and the improvement in color purity.

On the other hand, in the case where the peak wavelengths of emission colors do not match with continuous orders serving as conditions for mutual strengthening (reinforcement) through interference, for example, in the case where a part or all of the orders are discontinuous, there will be generated, between the peak wavelengths of the emission colors, wavelength(s) at which lights reinforce each other through interference. In general, the emission spectrum of an organic compound has a certain width with a full width at half maximum of 50 to 100 nm. Accordingly, in such a case, there will be generated, in regions between the peak wavelengths of the emission colors, portion(s) at which lights reinforce each other through interference. As a result, a considerable improvement in color purity can not be expected, and there may be rather occurred a phenomenon in which the color purity degrades. Therefore, the conditions of continuous orders of interference play an important role.

In the display apparatus exemplified here capable of displaying three primary colors of red, green, and blue (λ_{R}=620 nm, λ_{G}=520 nm, λ_{B}=450 nm), the above conditions can be satisfied particularly when m represents 4 or 5. The inventors have found that by adopting, for example, m of 5, that is, by using a 5th-order interference for R, using a 6th-order interference for G, and using a 7th-order interference for B, an improvement in the light extraction efficiency and an improvement in the color purity can be achieved at the same time.

However, it should be noted that the present invention is not particularly limited to three colors. The present invention can also be applied to a case where a four-wavelength light source having emission wavelengths of, for example, 650 nm, 570 nm, 500 nm, and 440 nm is used, and that the color reproduction range can also be made wider.

In other words, in the present invention, the optical paths between the interface on the reflecting electrode side of the light-emitting layer and the reflecting surface of the reflecting electrode for the respective emission colors are identical to one another. In addition, the following relational equations (1) and (2′) are preferably satisfied:

$$\begin{matrix}{λ}_{1} > {λ}_{2} > {λ}_{3} > ⋯ > {λ}_{n} \\ 2 {L}_{1} / {λ}_{1} + {δ}_{1} / 2 π = m \\ 2 {L}_{2} / {λ}_{2} + {δ}_{2} / 2 π = m + 1 \\ \begin{matrix}2 {L}_{3} / {λ}_{3} + {δ}_{3} / 2 π = m + 2 \\ ⋮\end{matrix} & ( 1 ) \\ 2 {L}_{n} / {λ}_{n} + {δ}_{n} / 2 π = m + n - 1 & ( {2}^{′} )\end{matrix}$$

wherein λ₁, λ₂, λ₃, . . . , λₙ represent emission peak wavelengths of the respective light-emitting elements of different emission colors, and L₁, L₂, L₃, . . . , Lₙ represent optical paths between the reflecting electrode and light-emitting layer of the respective light-emitting elements of different emission colors, δ₁, δ₂, δ₃, . . . , δₙ represent phase shift amounts for the respective emission colors at the reflecting electrodes and m represents a natural number and n represents a natural number more than 2.

However, it is not necessary that the light-emitting element array of the present invention strictly satisfies the conditions represented by the relational equations (2′). The array may have some degree of deviation from the conditions represented by the relational equations (2′) as long as an effect of improving the light extraction efficiency can be obtained utilizing interference.

To be specific, in the present invention, the following relational equations (1), (2), and (3) are satisfied:

$$\begin{matrix}{λ}_{1} > {λ}_{2} > {λ}_{3} > ⋯ > {λ}_{n} \\ {α}_{1} + {δ}_{1} / 2 π = m \\ {α}_{2} + {δ}_{2} / 2 π = m + 1 \\ \begin{matrix}{α}_{3} + {δ}_{3} / 2 π = m + 2 \\ ⋮\end{matrix} & ( 1 ) \\ {α}_{n} + {δ}_{n} / 2 π = m + n - 1 \\ \vert 2 {L}_{1} / {λ}_{1} - {α}_{1} \vert \leq 1 / 8 \\ \vert 2 {L}_{2} / {λ}_{2} - {α}_{2} \vert \leq 1 / 8 \\ \begin{matrix}\vert 2 {L}_{3} / {λ}_{3} - {α}_{3} \vert \leq 1 / 8 \\ ⋮\end{matrix} & ( 2 ) \\ \vert 2 {L}_{n} / {λ}_{n} - {α}_{n} \vert \leq 1 / 8 & ( 3 )\end{matrix}$$

In addition, from the viewpoint of the simplification of a production process, it is preferable that the thicknesses of carrier-transporting layers each disposed between the light-emitting layer and the reflecting electrode are the same irrespective of the emission color, and that the carrier-transporting layers extend over the plurality of light-emitting elements through gaps between adjacent light-emitting elements. Such a structure makes it possible to eliminate a step of performing patterning film formation for each element by using a mask or the like during film formation and to perform film formation at one time, so that the production process can be remarkably simplified. In addition, because the carrier-transporting layers extend over through gaps between adjacent light-emitting elements, it is possible to prevent a short circuit between the cathode 7 (light extraction electrode) and the anode 2 (reflecting electrode) due to, for example, a deviation in patterning of the organic layer.

However, it is to be noted that, as for the structure of an organic EL element, for a specific emission color, there is a case where various functional layers such as a carrier blocking layer are further needed, or a case where an improvement in the efficiency can be achieved only by a combination with a specific carrier-transporting layer. In such cases, by additionally providing an appropriate functional layer or by substituting a carrier-transporting layer, it is possible to achieve a further improvement in light extraction efficiency and a further improvement in color purity.

Hereinafter, each component of the light-emitting element array according to the present invention will be specifically described.

As shown in FIG. 1, a substrate 1 is composed of a support member 11, a TFT drive circuit 12, and a flattening layer 13. Examples of a material for use in the support member 11 include, but not particularly limited to, metals, ceramics, glass, and quartz. In addition, a flexible display apparatus can be produced by making TFTs on a flexible sheet such as a plastic sheet.

Anodes 2 each serving as a reflecting electrode are formed on the substrate 1. The anodes 2 are electrically connected to the TFT drive circuit 12 through contact holes 14. In addition, the anodes 2 are patterned for respective pixels, and are separated by element isolation films 23.

In this embodiment, each of the anodes 2 is composed of a reflective metal 21 and a transparent conductive film 22. By adopting the structure in which the transparent conductive film 22 contributes to an optical path, an increase in drive voltage, and a reduction in efficiency due to loss of a charge balance are prevented. In this case, the reflecting surface of the reflecting electrode corresponds to an interface between the reflective metal 21 and the transparent conductive film 22.

It is desirable that the reflective metal 21 has a reflectance at the interface with the transparent conductive film 22 of at least 50% or more, preferably 80% or more. Examples of a metal used as the reflective metal 21 include, but not particularly limited to, silver, aluminum, and chromium (including a silver alloy and an aluminum alloy).

As the transparent conductive film 22, there may be used an oxide conductive film, specifically, a compound film (ITO) composed of indium oxide and tin oxide, a compound film (IZO) composed of indium oxide and zinc oxide, or the like. The term “transparent” as employed herein refers to a state that the film has a transmittance of 80 to 100% with respect to visible light. To be more specific, it is desirable that the film has a complex refractive index κ of 0.05 or less, preferably 0.01 or less. This is because the complex refractive index κ shows the degree of absorption, and a small value for κ can suppress attenuation due to multiple reflections.

The thickness of the transparent conductive film 22, which depends on the refractive index of the film and an emission color, is preferably 50 nm or more. This is because driving at a lower voltage is advantageous from the viewpoint of saving power consumption. In addition, from the viewpoint of prevention of leakage, the thickness of the hole-transporting layer 3 is desirably set to fall within the range of 10 nm or more, preferably 10 to 200 nm, and more preferably 10 to 100 nm.

The organic compounds for use in the hole-transporting layer 3, the light-emitting layer 4, the electron-transporting layer 5, and the electron injection layer 6 may be a low-molecular material, a high-molecular material (polymer), or a combination of the both materials, and are not particularly limited. Any hitherto known material can be used as needed.

Hereinafter, examples of those compounds are enumerated.

As the hole transportable material, there are preferably used those having excellent mobility which facilitates the injection of holes from the anode 2 and the transportation of the injected holes to the light-emitting layer 4. In addition, a hole injection layer may be interposed between the anode 2 and the hole-transporting layer 3. Examples of low-molecular and high-molecular materials having hole injecting/transporting property include, but of course not limited to, a triarylamine derivative, a phenylenediamine derivative, a triazole derivative, an oxadiazole derivative, an imidazole derivative, a pyrazoline derivative, a pyrazolone derivative, an oxazole derivative, a fluorenone derivative, a hydrazone derivative, a stilbene derivative, a phthalocyanine derivative, a porphyrin derivative, poly(vinylcarbazole), poly(silylene), poly(thiophene), and other conductive polymers. A part of specific examples of the materials are shown below.

Low-molecular hole injecting/transporting material

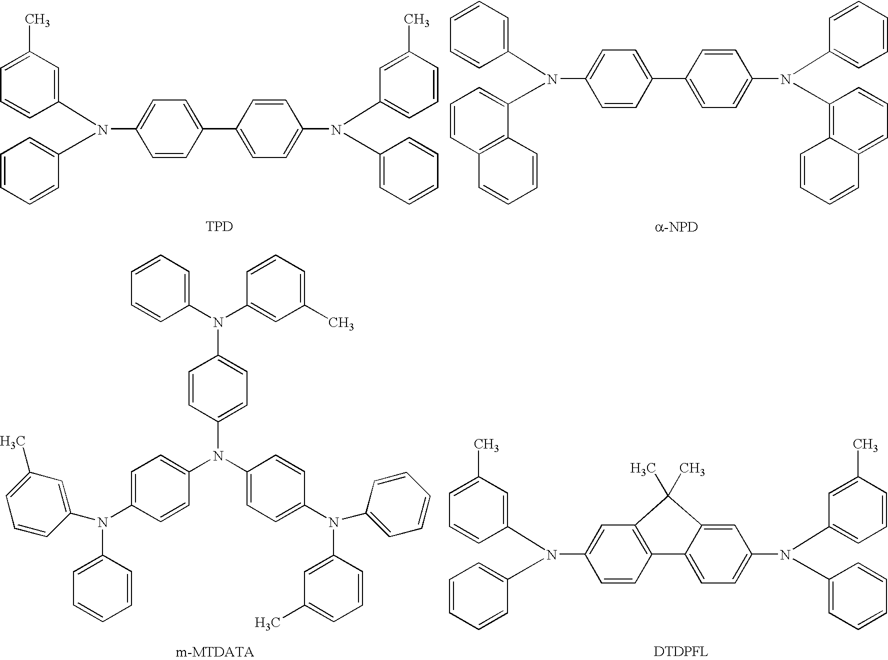

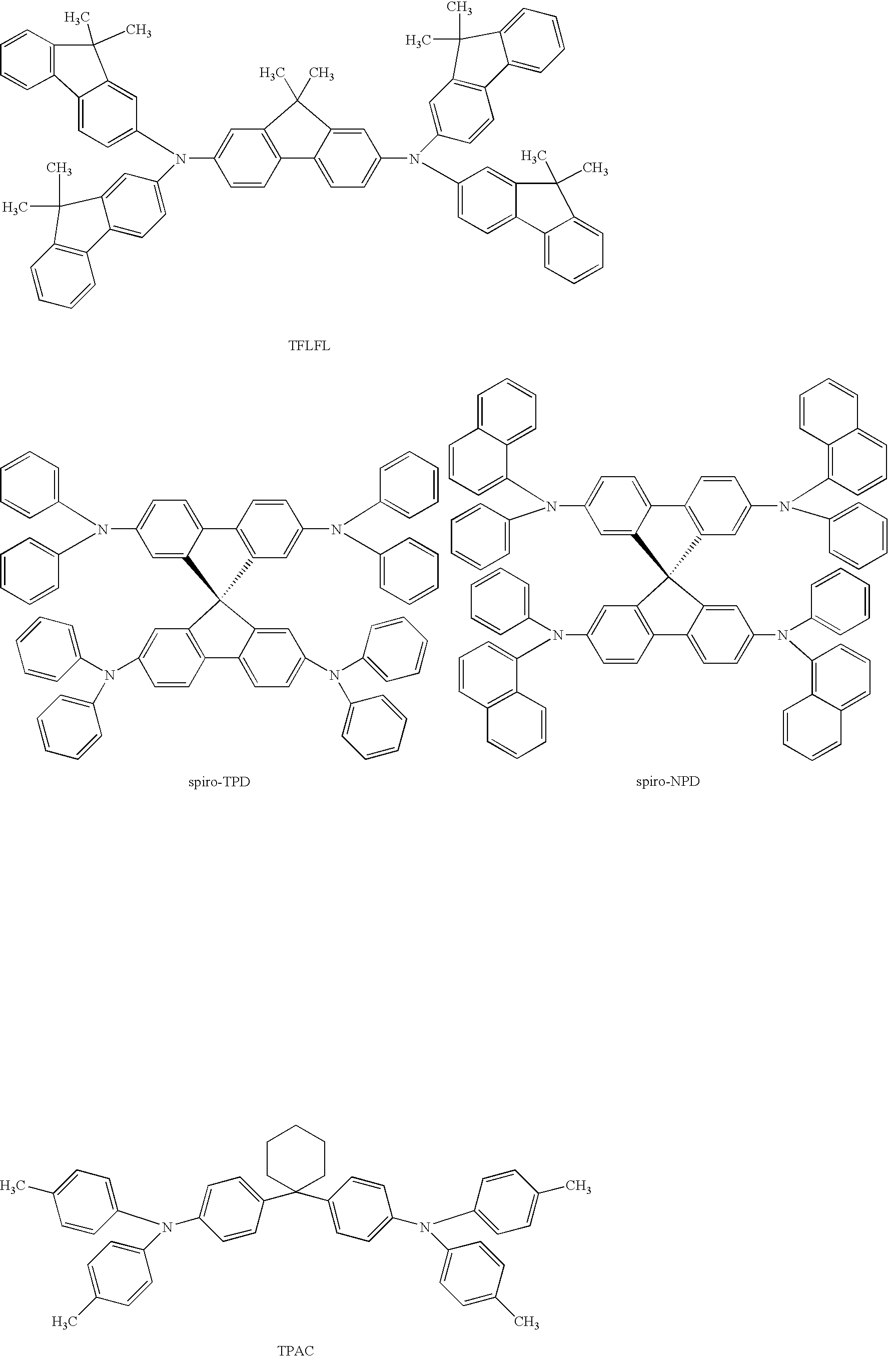

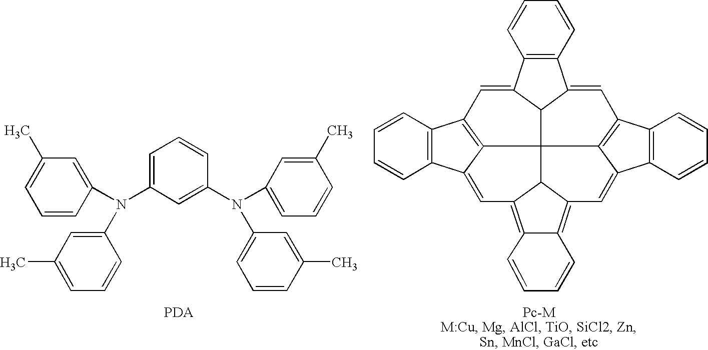

High-molecular hole transporting material

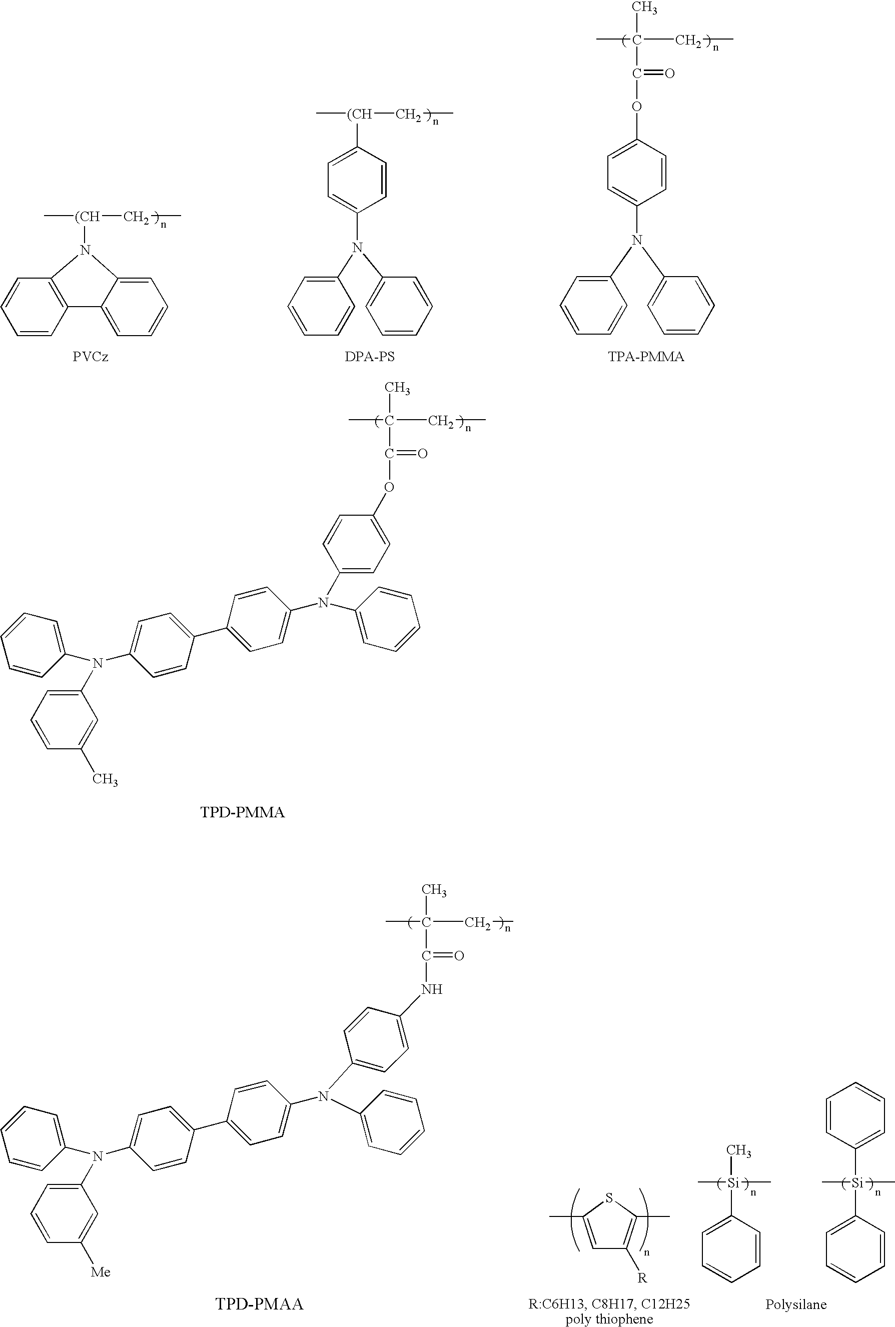

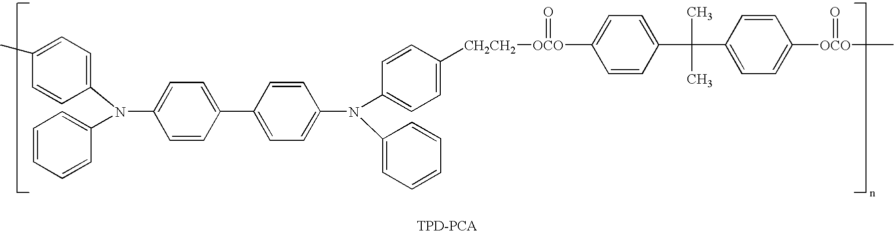

As a light-emitting material, a fluorescent dye or phosphorescent material having a high emission efficiency is used. A part of specific examples of the dye or material are enumerated below.

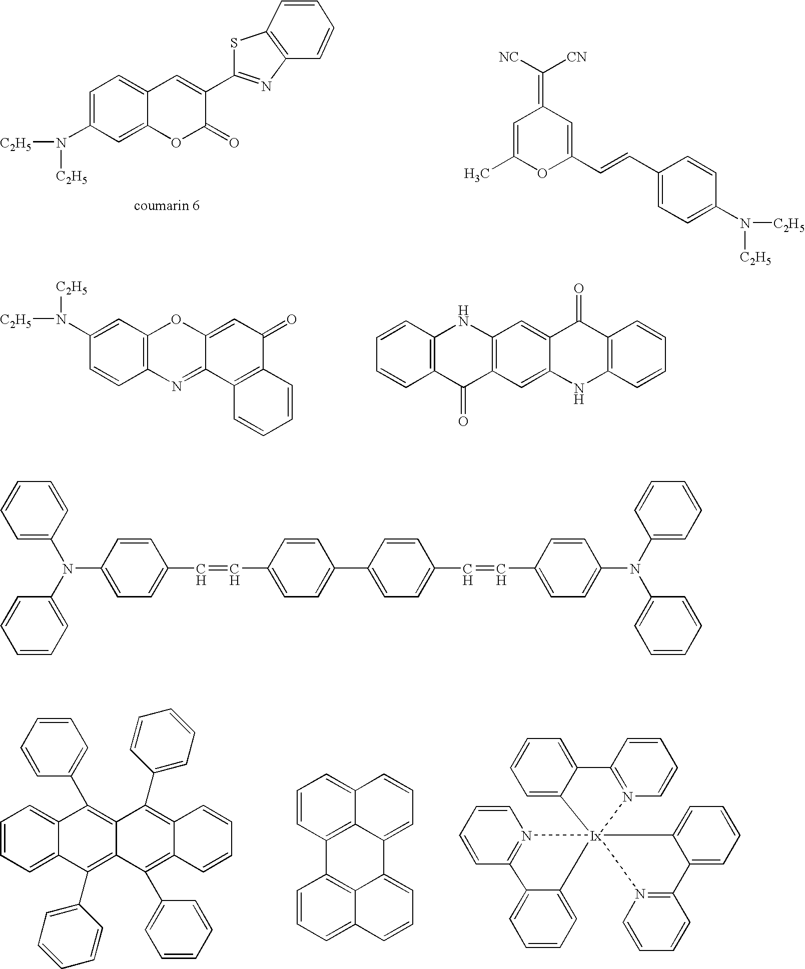

The electron transportable material can be arbitrarily selected from those having a function of transporting injected electrons to the light-emitting layer 4, and is selected in consideration of, for example, a balance with the carrier mobility of the hole-transporting material. Examples of a material having electron injecting/transporting property include, but of course not limited to, an oxadiazole derivative, an oxazole derivative, a thiazole derivative, a thiadiazole derivative, a pyrazine derivative, a triazole derivative, a triazine derivative, a perylene derivative, a quinoline derivative, a quinoxaline derivative, a fluorenone derivative, an anthrone derivative, a phenanthroline derivative, and an organometallic complex. A part of specific examples of the material are enumerated below.

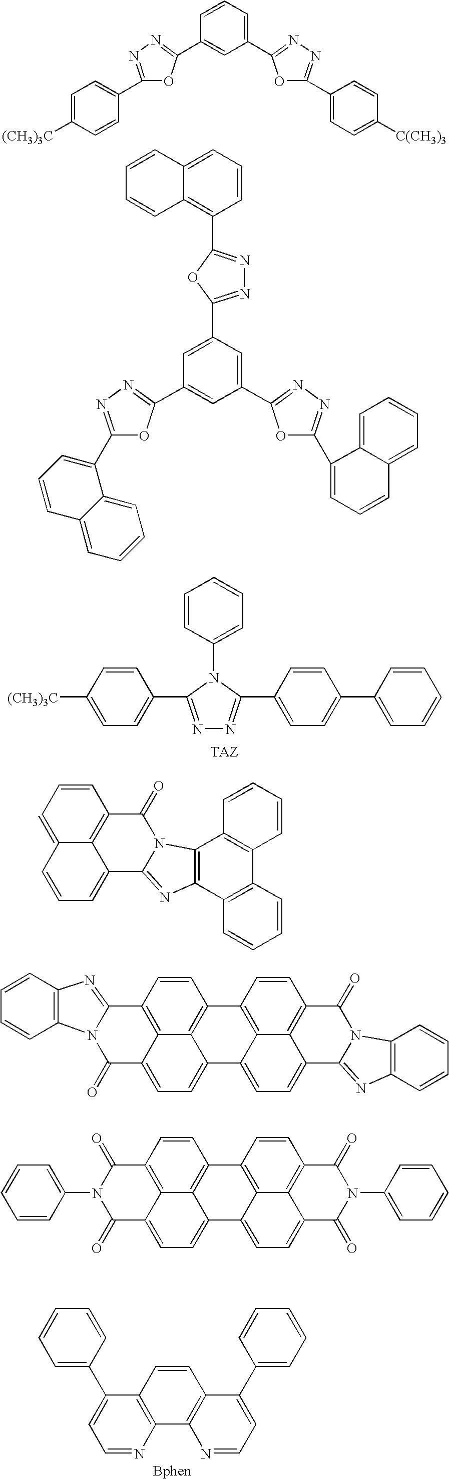

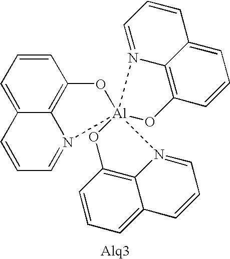

Further, as the electron-injecting material, electron-injecting property can be imparted to the above-mentioned electron transportable material by incorporating 0.1 percent to several tens percent of an alkali metal or alkali earth metal, or a compound thereof into the material. Although the electron injection layer 6 is not an indispensable layer, it is preferable to provide an electron injection layer of about 10 to 100 nm in thickness, for securing good electron-injecting property in consideration of damage given at the time of film formation of the cathode 7 in a subsequent production step.

These organic layers can be generally formed by means of, for example, a vacuum evaporation method, an ionized evaporation method, sputtering, or plasma. Alternatively, they can be formed by: dissolving an organic compound into an appropriate solvent; and applying the solution by means of a known application method such as spin coating, dipping, a casting method, an LB method, or an ink-jet method. In particular, when a film is formed by means of an application method, the film can be formed of such an organic compound in combination with an appropriate binder resin. The binder resin can be selected from a wide variety of binding resins, and examples of the binder resin include, but not limited to, a polyvinyl carbazole resin, a polycarbonate resin, a polyester resin, a polyallylate resin, a polystyrene resin, an ABS resin, a polybutadiene resins a polyurethane resin, an acrylic resin, a methacrylic resin, a butyral resin, a polyvinyl acetal resin, a polyamide resin, a polyimide resin, a polyethylene resin, a polyethersulfone resin, a diallyl phthalate resin, a phenol resin, an epoxy resin, a silicone resin, a polysulfone resin, and a urea resin. Further, these resins may be used singly or in combination as a copolymer. Moreover, a known additive such as a plasticizer, an antioxidant, or a UV absorber may be used in combination as needed.

As the cathode 7 serving as a light extraction electrode, the above-mentioned oxide conductive film such as ITO or IZO can be used. It is desirable to select appropriately a combination of the cathode 7 with the electron-transporting layer 5 and the electron injection layer 6 so as to provide good electron-injecting property. The cathode 7 can be formed by means of sputtering.

Alternatively, a semi-transmissive reflecting layer can be used as a light extraction electrode. The term “semi-transmissive reflecting layer” as herein employed refers to a layer which transmits a part of light and reflects another part of the light. In this case, the light extraction efficiency can be improved by utilizing not only the mutual reinforcement of lights due to the adjustment of the optical path between the above-mentioned emission position and the reflecting surface of the reflecting electrode but also resonance due to repeated reflection of light between the reflecting surface of the semi-transmissive reflecting layer and the reflecting surface of the reflecting electrode. In order to utilize the mutual reinforcement, it is necessary that the following relational equations (5) are established when the emission peak wavelengths of the respective light-emitting elements of different emission colors are sequentially represented by λ₁, λ₂, λ₃, . . . in the order of decreasing wavelength, and the optical paths between the reflecting surface of the semi-transmissive reflecting layer and the reflecting surface of the reflecting electrode of the light-emitting elements are represented by Lₐ₁, Lₐ₂, Lₐ₃, . . . , Lₐₙ respectively in correspondence with the emission peak wavelengths λ₁, λ₂, λ₃, . . . , λₙ

$$2 {L}_{a 1} / {λ}_{1} + {δ}_{a 1} / 2 π = {m}^{*} \\ 2 {L}_{a 2} / {λ}_{2} + {δ}_{a 2} / 2 π = {m}^{*} + 1 \\ \begin{matrix}2 {L}_{a 3} / {λ}_{3} + {δ}_{a 3} / 2 π = {m}^{*} + 2 \\ ⋮\end{matrix} \\ 2 {L}_{an} / {λ}_{n} + {δ}_{an} / 2 π = {m}^{*} + n - 1 \qquad ( 5 )$$

wherein the values m*, m*+1, m*+2, . . . , m*+n−1 on the right sides in the relational equations (5) each represent a natural number, and sums of phase shift amounts δₐ₁, δₐ₂, δₐ₃, . . . , δₐₙ are each an amount determined such that δₐ₁=δₕ₁+δᵣ₁ when phase shift amounts at the time of reflection by the semi-transmissive reflecting layer are represented by δₕ₁, δₕ₂, . . . , δₕₙ and phase shift amounts at the reflecting electrode are represented by δᵣ₁, δᵣ₂, . . . , δᵣₙ respectively, and takes a value within the range of 0 or more and less than 2π.

The protective layer 8 is provided for the purpose of preventing contact with oxygen, water, or the like. Examples of a material of the protective layer 8 include a metal nitride film such as of silicon nitride or silicon nitride oxide; a metal oxide film such as of tantalum oxide; a diamond thin film; a polymer film such as of a fluororesin, polyparaxylene, polyethylene, a silicone resin, or a polystyrene resin; and a photocurable resin. Alternatively, an element may be covered with glass, a gas impermeable film, a metal, or the like, or an element itself may be packaged in an appropriate sealing (or encapsulating) resin. Moreover, in order to improving moisture resistance, a hygroscopic material may be contained in the protective layer 8.

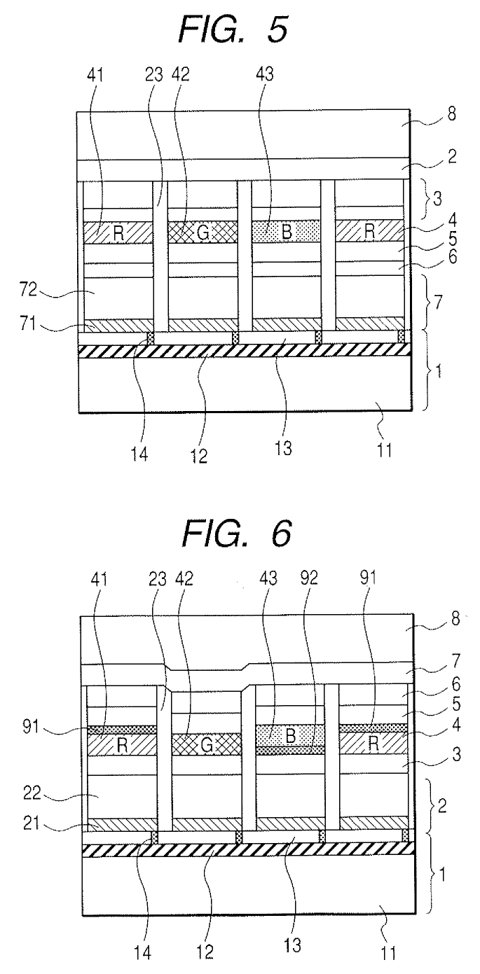

The foregoing description has been made by taking as an example the structure in which the anode 2 is present on the TFT drive circuit 12 side. However, a reverse structure such as shown in FIG. 5 may also be adopted. That is, there may be adopted a structure obtained by sequentially stacking a cathode 7 serving as a reflecting electrode and composed of a reflective metal 71 and a transparent conductive film 72, an electron injection layer 6, an electron-transporting layer 5, a light-emitting layer 4, a hole-transporting layer 3, an anode 2 serving as a light extraction electrode, and a protective layer 8. In such a structure, as a donor with which the electron injection layer 6 serving as a carrier transportation-promoting layer is doped, a dopant material for the electron-transporting layer 5 such as an alkali metal or alkali earth metal, or a compound thereof described later can be used.

Furthermore, the present invention can also be applied to the so-called bottom emission structure in which a light extraction electrode is formed on a transparent substrate, an organic layer and a reflecting electrode are stacked thereon, and light is extracted from the substrate side.

In addition, although the above description has been made by taking an EL element having the so-called double hetero structure as an example, the present invention can also be applied to an EL element having the single hetero structure.

Furthermore, the present invention is applicable to not only the so-called active matrix type display apparatus having a drive circuit for controlling the driving of each element but also a passive matrix type display apparatus in which light is emitted at a point of intersection of stripe-shaped electrodes by duty driving.

FIG. 4 shows another embodiment of the present invention. The structure shown in the figure is obtained by sequentially providing, on a substrate 1, an anode 2, a hole-transporting layer 3, a light-emitting layer 4, an electron-transporting layer 5, an electron injection layer 6, a cathode 7, and a protective layer 8. The anode 2 functions as a reflecting electrode, and the cathode 7 functions as a light extraction electrode.

In this embodiment, the anode 2 is composed of a single-layer reflective electrode, and the hole-transporting layer 3 is composed of a first hole-transporting layer 31 and a second hole-transporting layer 32. The first hole-transporting layer 31 is doped with an acceptor, and functions as a carrier transportation-promoting layer. The second hole-transporting layer 32 is undoped, and functions as a carrier-transporting layer. In this embodiment, because the first hole-transporting layer 31 serving as a carrier transportation-promoting layer contributes to an optical path, an increase in the drive voltage and a reduction in the efficiency due to loss of a charge balance are prevented.

It is preferable that the thickness of the first hole-transporting layer 31 is within the range of 400 to 700 nm in consideration of the diffusion of the acceptor and a reduction in the drive voltage.

For the anode 2 which can be used here, it is necessary to have a high reflectivity at an interface with the first hole-transporting layer 31 and to facilitate the injection of holes. In terms of physical properties, it is desirable to have a large refractive index difference and a large work function. From this viewpoint, nickel, chromium, or the like can be used for the anode 2, but the material for the anode is not particularly limited. Aluminum, a silver alloy, and the like can also be used because of having an effect of promoting the injection of the acceptor used in the first hole-transporting layer 31. In addition, an anode composed of two layers of a reflective metal and a transparent conductive film described above can also be used.

Examples of the acceptor used in the first hole-transporting layer 31 include a Lewis acid such as PTSA, TCNQ, FeCl₃, or TBAHA; a metal halide; and a salt of arylamine and a metal halide. To be specific, by doping the above-mentioned hole-transporting material with 0.1 percent to several tens percent of an acceptor, it becomes possible to increases the carrier amount and to allow a large current to flow at a low voltage. Therefore, even when the hole-transporting layer 3 has a total thickness such as of several hundreds nanometers to one thousand and several hundreds nanometers, it is possible to perform driving without any increase in the voltage.

FIG. 6 shows still another embodiment of the present invention. The structure shown in the figure is obtained by sequentially providing, on a substrate 1, an anode 2, a hole-transporting layer 3, a light-emitting layer 4, an electron-transporting layer 5, an electron injection layer 6, a cathode 7, and a protective layer 8. The anode 2 functions as a reflecting electrode, and the cathode 7 functions as a light extraction electrode.

In this embodiment, a hole-blocking layer 91 is provided between the R light-emitting layer 41 and the electron-transporting layer 5, and an electron-blocking layer 92 is provided between the B light-emitting layer 43 and the hole-transporting layer 3. According to this embodiment, the presence of the carrier-blocking layers can improve the exciton generation efficiency and can further improve the light extraction efficiency.

As a material for the hole-blocking layer 91, there may preferably be included those materials having an HOMO level lower than that of an adjacent light-emitting layer or electron-transporting layer. Examples of the material include dimethyl diphenyl phenanthroline (BCP), BAlq, and triazine. As a material for the electron-blocking layer 92, there may preferably be included those materials having an LUMO level higher than that of an adjacent light-emitting layer or hole-transporting layer. An example of the material is TPD.

It is preferable that the thickness of each of the hole-blocking layer 91 and the electron-blocking layer 92 falls within the range of 5 to 50 nm in consideration of a reduction in drive voltage. In particular, the thickness of the electron-blocking layer 92 is preferably set to fall within the range of 5 to 30 nm so that the optical paths satisfy the relational equations (2′).

Hereinafter, the present invention will be described more specifically by way of examples. However, the present invention is not limited to these examples.

### EXAMPLE 1

A display apparatus of three colors of red, green, and blue with the structure shown in FIG. 1 was produced by means of the following method.

A TFT drive circuit 12 composed of low-temperature polysilicon was formed on a glass substrate as a support member 11, and a flattening layer 13 composed of an acrylic resin was formed thereon to prepare a substrate 1. A silver alloy (AgPdCu) as a reflective metal 21 was formed thereon in a thickness of about 100 nm by means of a sputtering method, followed by patterning. Furthermore, IZO as a transparent conductive film 22 was formed thereon in a thickness of 620 nm by means of a sputtering method, followed by patterning, thereby forming an anode 2 (reflecting electrode). Furthermore, an element isolation film 23 was formed of an acrylic resin, whereby the substrate with the anode was produced. The substrate was subjected to ultrasonic cleaning with isopropyl alcohol (IPA), and was then subjected to boiling cleanings, followed by drying. Furthermore, the substrate was subjected to UV/ozone cleaning, and organic compounds were then used to form films by means of vacuum evaporation.

First, Compound [I] shown below was used to form a film on all pixels in a thickness of 50 nm as a common hole-transporting layer 3. At this time, the degree of vacuum was 1×10⁻⁴ Pa and the evaporation rate was 0.2 nm/sec.

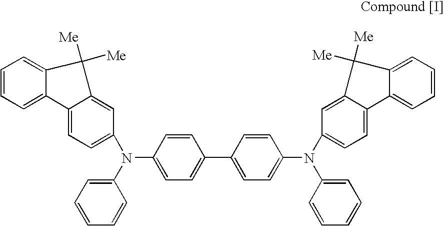

Next, as the light-emitting layers 4, light-emitting layers for R, G, and B were formed respectively by using a shadow mask. As a red-light-emitting layer 41, Alq₃ as a host and a light-emitting compound 4-(dicyanomethylene)-2-methyl-6-(p-dimethylaminostyryl)-4H-pyran (DCM) were co-evaporated (at a weight ratio of 99:1) to provide a light-emitting layer having a thickness of 30 nm. As a green-light-emitting layer 42, Alq₃ as a host and a light-emitting compound coumarin 6 were co-evaporated (at a weight ratio of 99:1) to provide a light-emitting layer having a thickness of 30 nm. As a green-light-emitting layer 43, Compound [II] as a host shown below and a light-emitting compound Compound [III] shown below were co-evaporated (at a weight ratio of 80:20) to provide a light-emitting layer having a thickness of 30 nm. The film formation was performed under the conditions during evaporation of a degree of vacuum of 1×10⁻⁴ Pa and a film formation rate of 0.2 nm/sec.

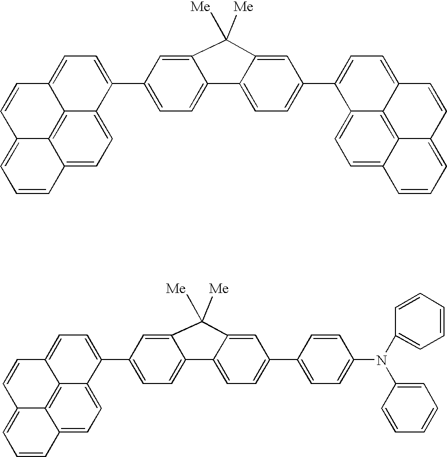

Furthermore, as a common electron-transporting layer 5, bathophenanthroline (Bphen) was vacuum-evaporated to form a film having a thickness of 30 nm. The evaporation was performed under the conditions of a degree of vacuum of 1×10⁻⁴ Pa and a film formation rate of 0.2 nm/sec.

Next, as a common electron injection layer 6, Bphen and Cs₂CO₃ were co-evaporated (at a weight ratio of 90:10) to form a film having a thickness of 20 nm. The evaporation was performed under the conditions of a degree of vacuum of 3×10⁻⁴ Pa and a film formation rate of 0.2 nm/sec.

The substrate having layers up to and including the electron injection layer 6 formed thereon was transferred into a sputtering apparatus without breaking the vacuum, and then an ITO film having a thickness of 60 nm was formed as a cathode 7 (light extraction electrode). Furthermore, as a protective layer 8, a silicon nitride oxide film was formed in a thickness of 700 nm, whereby a display apparatus was obtained.

The optical paths between an emission position (interface between the light-emitting layer 4 and the hole-transporting layer 3) and the reflecting surface (interface between the reflective metal 21 and the transparent conductive film 22) of the reflecting electrode of the display apparatus for the respective colors are as shown below. The orders of interference are 5, 6, and 7 (m=5) for red (R), green (G), and blue (B), respectively.
R(λ_{R}=620 nm): 1,350 nm
G(λ_{G}=520 nm): 1,400 nm
B(λ_{B}=450 nm): 1,450 nm

Table 1 shows the emission efficiency and chromaticity coordinates of each of R, G, and B when displaying a white color (chromaticity coordinates: 0.32, 0.33, 300 cd/m²) on the thus obtained display apparatus. As is seen from Table 1, good results were obtained for both the efficiency and the color purity.

### EXAMPLE 2

A display apparatus was made by following the same procedure as in Example 1 with the exception that the thickness of the transparent conductive film 22 constituting the anode 2 was changed to 480 nm.

The optical paths between an emission position (interface between the light-emitting layer 4 and the hole-transporting layer 3) and the reflecting surface (interface between the reflective metal 21 and the transparent conductive film 22) of the reflecting electrode of the display apparatus for the respective colors are as shown below. The orders of interference are 4, 5, and 6 (m=4) for R, G, and B, respectively.
P(λ_{R}=620 nm): 1065 nm
G(λ_{G}=520 nm): 1,100 nm
B(λ_{B}=450 nm): 1,150 nm

Table 1 shows the emission efficiencies and chromaticity coordinates determined in the same manner as in Example 1. As is seen from Table 1, good results were obtained for both the efficiency and the color purity.

### EXAMPLE 3

A display apparatus was made by following the same procedure as in Example 1 with the exception that, as shown in FIG. 4, the anode 2 (reflecting electrode) was composed only of a silver alloy (AgPdCu) of a thickness of 100 nm, and a first hole-transporting layer 31 doped with an acceptor and a second hole-transporting layer 32 being undoped were formed as a hole-transporting layer 3.

The first hole-transporting layer 31 was formed by co-evaporating Compound [I] used in Example 1 and FeCl₃ (at a weight ratio of 95:5, and in a thickness of 580 nm). The evaporation was performed under the conditions of a degree of vacuum of 1×10⁻⁴ Pa and a film formation rate of 1.0 nm/sec. The second hole-transporting layer 32 was formed by evaporating Compound [I] used in Example 1 in a thickness of 20 nm. The evaporation was performed under the conditions of a degree of vacuum of 1×10⁻⁴ Pa and a film formation rate of 0.2 nm/sec.

The optical paths between an emission position (interface between the light-emitting layer 4 and the hole-transporting layer 3) and the reflecting surface (interface between the anode 2 and the hole-transporting layer 3) of the reflecting electrode of the display apparatus for the respective colors are as shown below. The orders of interference are 4, 5, and 6 (m=4) for R, G, and B, respectively.
R(λ_{R}=620 nm): 1,055 nm
G(λ_{G}=520 nm): 1,090 nm
B(λ_{B}=450 nm): 1,150 nm

Table 1 shows emission efficiencies and chromaticity coordinates determined in the same manner as in Example 1. As is seen from Table 1, good results were obtained for both the efficiency and the color purity.

### EXAMPLE 4

A display apparatus was made by following the same procedure as in Example 2 with the exception that, as shown in FIG. 6, a hole-blocking layer 91 was provided between the read-light-emitting layer 41 and the electron-transporting layer 5, and an electron-blocking layer 92 was provided between the blue-light-emitting layer 43 and the hole-transporting layer 3.

As the hole-blocking layer 91, dimethyl diphenyl phenanthroline (BCP) was formed into a film in a thickness of 5 nm. As the electron-blocking layer 92, TPD was formed into a film in a thickness of 5 nm.

The optical paths between an emission position (For R and G: an interface between the light-emitting layer 4 and the hole-transporting layer 3; For B: an interface between the light-emitting layer 4 and the electron-blocking layer 92) and the reflecting surface (interface between the reflective metal 21 and the transparent conductive film 22) of the reflecting electrode of the display apparatus for the respective colors are shown below. The orders of interference are 4, 5, and 6 (m=4) for R, G, and B, respectively.
R(λ_{R}=620 nm): 1,065 nm
G(λ_{G}=520 nm): 1,100 nm
B(λ_{B}=450 nm): 1,160 nm

Table 1 shows emission efficiencies and chromaticity coordinates determined in the same manner as in Example 1. As is seen from Table 1, better efficiencies were obtained owing to the effect of provision of the carrier-blocking layers.

### COMPARATIVE EXAMPLE 1

A display apparatus was made by following the same procedure as in Example 1 with the exception that the thickness of the transparent conductive film 22 constituting the anode 2 was changed to 20 nm.

The optical paths between an emission position (interface between the light-emitting layer 4 and the hole-transporting layer 3) and the reflecting surface (interface between the reflective metal 21 and the transparent conductive film 22) of the reflecting electrode of the display apparatus for the respective colors are as shown below.
R(λ_{R}=620 nm): 120 nm
G(λ_{G}=520 nm): 120 nm
B(λ_{B}=450 nm): 160 nm

Table 1 shows emission efficiencies and chromaticity coordinates determined in the same manner as in Example 1. As is seen from Table 1, chromaticity coordinates degraded for all of R, G, and B, and the efficiencies lowered particularly for G and B.

### COMPARATIVE EXAMPLE 2

A display apparatus was made by following the same procedure as in Example 1 with the exception that the thickness of the transparent conductive film 22 constituting the anode 2 was changed to 1,000 nm.

The optical paths between an emission position (interface between the light-emitting layer 4 and the hole-transporting layer 3) and the reflecting surface (interface between the reflective metal 21 and the transparent conductive film 22) of the reflecting electrode of the display apparatus for the respective colors are as shown below. The orders of interference are 8, 10, and 12 for R, G, and B, respectively.
R(λ_{R}=620 nm): 2,120 nm
G(λ_{G}=520 nm): 2,200 nm
B(λ_{B}=450 nm): 2,300 nm

Table 1 shows emission efficiencies and chromaticity coordinates determined in the same manner as in Example 1. As is seen from Table 1, as compared to the case of Example 2 in which 4th, 5th, and 6th order interference was utilized, both the color purity and the efficiency lowered for all of R, G, and B.

TABLE 1

| | | R | G | B |
|---|---|---|---|---|
| Example 1 | Efficiency (cd/A) | 8.6 | 16.0 | 3.0 |
| | Chromaticity | 0.69, 0.31 | 0.24, 0.72 | 0.14, 0.12 |
| | coordinates (x, y) | | | |
| Example 2 | Efficiency (cd/A) | 7.4 | 16.0 | 3.2 |
| | Chromaticity | 0.69, 0.31 | 0.20, 0.74 | 0.15, 0.11 |
| | coordinates (x, y) | | | |
| Example 3 | Efficiency (cd/A) | 8.1 | 16.0 | 3.6 |
| | Chromaticity | 0.69, 0.31 | 0.20, 0.74 | 0.15, 0.13 |
| | coordinates (x, y) | | | |
| Example 4 | Efficiency (cd/A) | 7.8 | 14.4 | 3.2 |
| | Chromaticity | 0.70, 0.31 | 0.18, 0.74 | 0.14, 0.13 |
| | coordinates (x, y) | | | |
| Comparative | Efficiency (cd/A) | 9.8 | 13.0 | 1.7 |
| Example 1 | Chromaticity | 0.67, 0.33 | 0.34, 0.63 | 0.14, 0.28 |
| | coordinates (x, y) | | | |
| Comparative | Efficiency (cd/A) | 6.2 | 13.6 | 2.7 |
| Example 2 | Chromaticity | 0.64, 0.36 | 0.29, 0.68 | 0.14, 0.13 |
| | coordinates (x, y) | | | |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2005-226658, filed Aug. 4, 2005 and 2006-189960, filed Jul. 11, 2006, which are hereby incorporated by reference herein in their entirety.

What is claimed is:

1. A light-emitting element array having
a plurality of light-emitting elements of different emission colors
each comprising
a light extraction electrode,
a reflecting electrode, and
an organic layer disposed between the electrodes,
said organic layer comprising
a light-emitting layer and
a carrier-transporting layer disposed between the light-emitting layer and the reflecting electrode,
wherein the geometrical distances between the reflecting electrode and light-emitting layer are the same irrespective of the emission color, and
the following relational equations (1), (2), and (3) are satisfied:
$$\begin{matrix}{λ}_{1} > {λ}_{2} > {λ}_{3} > ⋯ > {λ}_{n} \\ {α}_{1} + {δ}_{1} / 2 π = m \\ {α}_{2} + {δ}_{2} / 2 π = m + 1 \\ \begin{matrix}{α}_{3} + {δ}_{3} / 2 π = m + 2 \\ ⋮\end{matrix} & ( 1 ) \\ {α}_{n} + {δ}_{n} / 2 π = m + n - 1 \\ \vert 2 {L}_{1} / {λ}_{1} - {α}_{1} \vert \leq 1 / 8 \\ \vert 2 {L}_{2} / {λ}_{2} - {α}_{2} \vert \leq 1 / 8 \\ \begin{matrix}\vert 2 {L}_{3} / {λ}_{3} - {α}_{3} \vert \leq 1 / 8 \\ ⋮\end{matrix} & ( 2 ) \\ \vert 2 {L}_{n} / {λ}_{n} - {α}_{n} \vert \leq 1 / 8 & ( 3 )\end{matrix}$$
wherein λ₁, λ₂, λ₃, . . . , λₙ represent emission peak wavelengths of the respective light-emitting elements of different emission colors,
δ₁, δ₂, δ₃, . . . , δₙ represent phase shift amounts for the respective emission colors of the reflecting electrode,
L₁, L₂, L₃, . . . , Lₙ) represent optical paths between the reflecting electrode and light-emitting layer of the respective light-emitting elements of different emission colors,
m represents a natural number, and
n represents a natural number more than 2.

2. The light-emitting element array according to claim 1, wherein thicknesses of the carrier-transporting layers are the same irrespective of the emission color, and the carrier-transporting layers comprise a common layer which extends over the plurality of light-emitting elements through gaps between adjacent light-emitting elements.

3. The light-emitting element array according to claim 1, wherein n is 3, and the emission colors of the light-emitting elements are at least three colors of red, green, and blue.

4. The light-emitting element array according to claim 1, wherein the emission colors of the light-emitting elements include at least three colors of red, green, and blue, and m in the relational equations (1) represents 4 or 5.

5. The light-emitting element array according to claim 1, wherein the reflecting electrode comprises a reflective metal and a transparent conductive film, and the transparent conductive film is on a side of the reflecting electrode which is in contact with the organic layer.

6. The light-emitting element array according to claim 5, wherein the organic layer being in contact with the transparent conductive film has a thickness of 10 nm or more.

7. The light-emitting element array according to claim 1, wherein the light extraction electrode comprises a semi-transmissive reflecting layer, and an optical path between a reflecting surface of the semi-transmissive reflecting layer and the reflecting surface of the reflecting electrode is such an optical path as to intensify light by resonance.

8. A display apparatus comprising the light-emitting element array set forth in claim 1.
